(19) United States
(12) Patent Application Publication
(10) Pub. No.: US 2007/0120269 A1
(43) Pub. Date: May 31, 2007

(54) Flip chip package and manufacturing method of the same

(75) Inventors: Chueh-An Hsieh, Kaohsiung (TW); Li-Cheng Tai, Kaohsiung (TW)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/511,428

(22) Filed: Aug. 29, 2006

(30) Foreign Application Priority Data
Nov. 30, 2005 (TW) 94142184

(51) Int. Cl. H01L 23/48

(52) U.S. Cl. 257/778

(57) ABSTRACT

A flip chip package including a chip structure, a substrate and an under-fill is provided. The chip structure includes a base, a number of pads, a first passivation layer, a second passivation layer and a number of bumps. The pads are formed on the base. The first passivation layer is formed on the base and exposes the pads. The second passivation layer formed on the first passivation layer has a number of first openings and at least a second openings. The first openings are positioned on the pads. The second openings are positioned on the area other than the pads. The width at the bottom of the second opening is larger than the width of the second opening at the top. The bumps are formed on the pads. The substrate has a number of connecting points corresponding to the bumps.

This application claims the benefit of Taiwan application Serial No. 094142184, filed Nov. 30, 2005, the subject matter of which is incorporated herein by reference.

### BACKGROUND OF THE INVENTION

1. Field of the Invention

The invention relates in general to a flip chip package and manufacturing method of the same, and more particularly to an anti-stress flip chip package and manufacturing method of the same.

2. Description of the Related Art

Referring to FIG. 1A to FIG. 1F, a flow chart of forming a conventional flip chip package is shown. The process of manufacturing a flip chip package includes the following steps. Firstly, as shown in FIG. 1A, a first passivation layer 103 is formed on a base 101 and a number of pads 105 are exposed. Then, as shown in FIG. 1B, a second passivation layer 107 is formed on the first passivation layer 103, and a number of openings 109 are formed by applying exposure and development. Next, as shown in FIG. 1C, an under bump metallurgy (UBM) layer 111 is deposited on a second passivation layer 107, and the UBM layer 111 is patterned. Afterwards, as shown in FIG. 1D, a number of bumps 113 are formed on the UBM layer 111 to form a chip structure 120.

Following the formation of the chip structure 120, the step of bonding the flip chip is applied. As shown in FIG. 1E, after the chip structure 120 is formed, the chip structure 120 is flipped and bonded such that one end of the bumps 113 is connected to a number of connecting points 117 disposed on a substrate 115. Lastly, an under-fill 119 is filled between the substrate 115 and the chip structure 120 such that a flip chip package 100 is formed.

After the flip chip package 100 is formed, the manufacturers would normally test the reliability of the flip chip package 100. The reliability test includes the factors such as temperature change, pressure change and mechanic change. After several testing cycles, detachment may occur between the substrate 115 and the chip structure 120. Detachment may occur between the bumps 113 and the connecting points 117 of the substrate 115, between the bumps 113 and the pads 105, or between the under-fill 119 and the second passivation layer 107. The detachment occurs due to insufficient cohesion and adhesion between the bumps 113 and the connecting points 117, between the bumps 113 and the pads 105, or between the under-fill 119 and the second passivation layer 107. Consequently, product reliability and product competitiveness are jeopardized.

### SUMMARY OF THE INVENTION

It is therefore an object of the invention to provide a flip chip package and manufacturing method of the same capable of improving anti-stress capability and reliability of package product.

The invention achieves the above-identified object by providing a flip chip package. The flip chip package includes a chip structure, a substrate and an under-fill. The chip structure includes a base, a number of pads, a first passivation layer, a second passivation layer and a number of bumps. The pads are formed on the base. The first passivation layer formed on the base exposes the pads. The second passivation layer formed on the first passivation layer has a number of first openings and at least a second opening. The first openings are positioned on the pads. The second openings are positioned on the area other than the pads. The width at the bottom of the second opening is larger than the width at the top of a second opening. The bottom of the second opening faces the first passivation layer. The bumps are formed on the pads. The substrate has a number of connecting points corresponding to the bumps. The connecting points are electrically connected to the bumps respectively.

The invention further achieves the above-identified object by providing a method of forming a flip chip package. The method includes the following steps. Firstly, a base is provided. Then, a first passivation layer and a number of pads are formed on the base. The pads are exposed in the first passivation layer. Next, a second passivation layer is formed on the first passivation layer and developed to form a number of first openings and at least a second opening. The width at the bottom of a second opening is larger than the width at the top of a second opening. The bottom of a second opening faces the first passivation layer. Afterwards, a number of bumps are formed inside the first openings, and the base is divided to form a number of chip structures. Next, a substrate is provided. Then, the chip structures are flipped and bonded on the substrate. Lastly, an under-fill is filled between the chip structure and the substrate.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A to FIG. 1F illustrate a flow chart of forming a conventional flip chip package;

FIG. 2A to FIG. 2F are a flow chart of forming a chip structure;

FIG. 3A to FIG. 3B are a flowchart of forming a flip chip package; and

FIG. 4 illustrates the formation of an undercut on a second passivation layer.

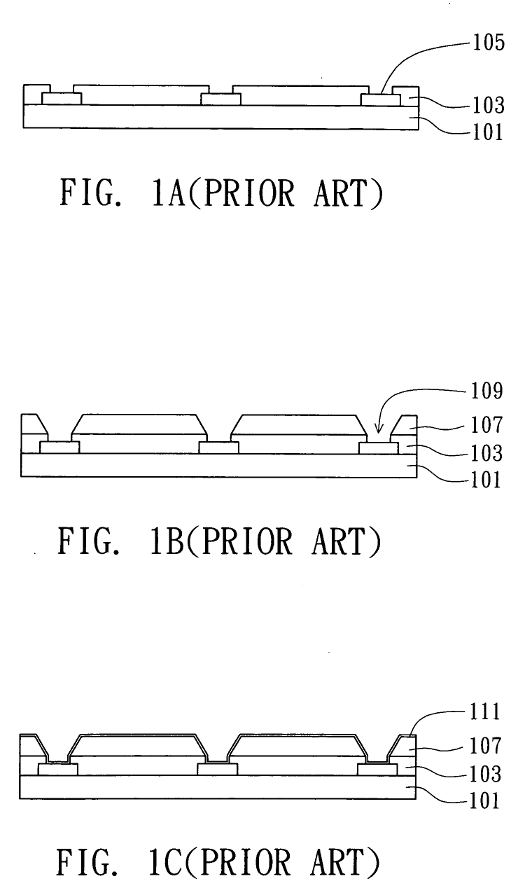

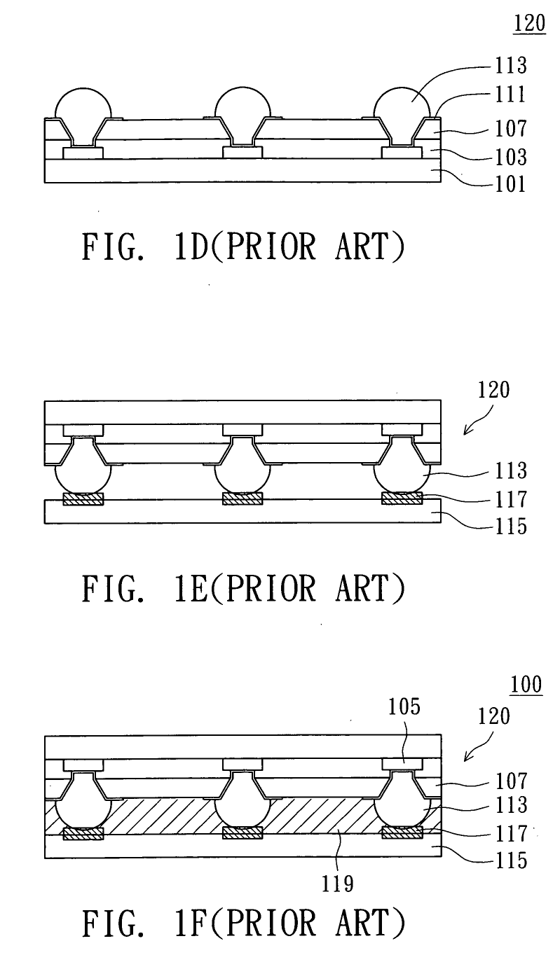

### DETAILED DESCRIPTION OF THE INVENTION

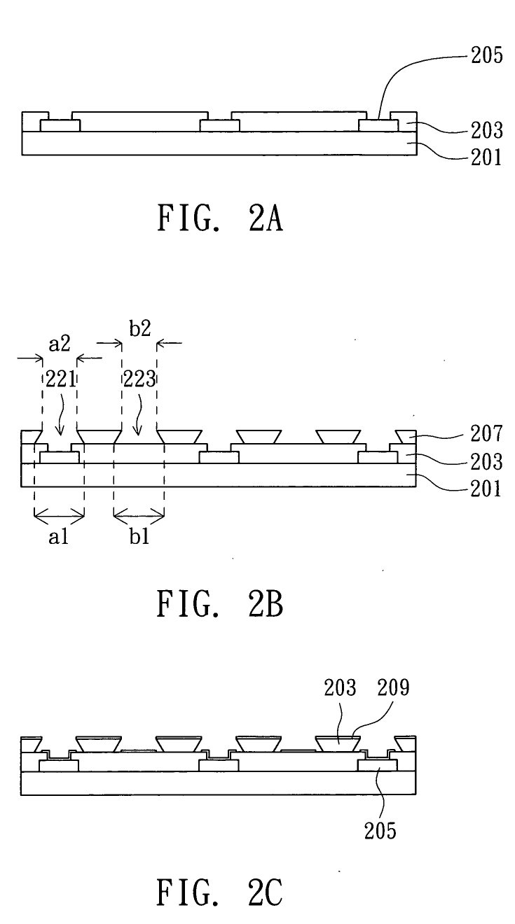

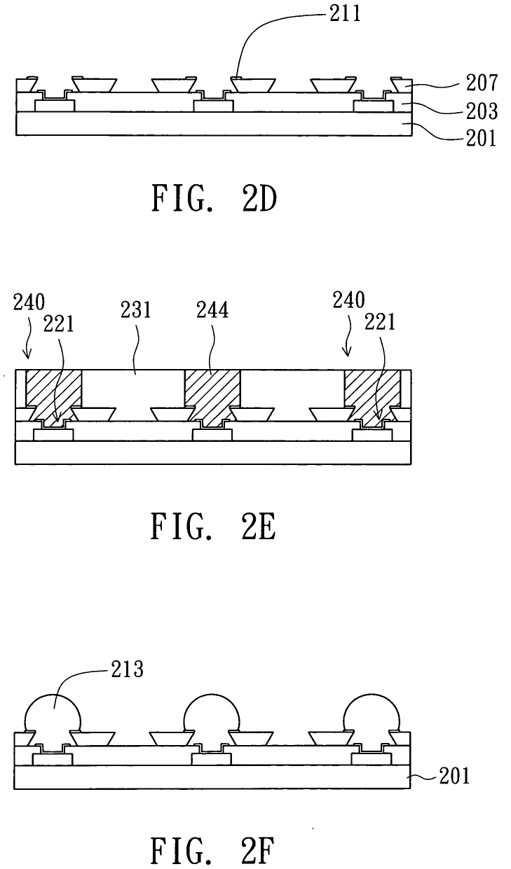

Referring to FIG. 2A to FIG. 2F, a flow chart of forming a chip structure is shown. As shown in FIG. 2A, a first passivation layer 203 is formed on the base 201, and a number of pads 205 are exposed. As shown in FIG. 2B, a second passivation layer 207 is further formed on the first passivation layer 203, and a number of first openings 221 and at least a second opening 223 are formed on the second passivation layer 207. The width b1 at the bottom of the second opening 223 is larger than the width b2 at the top of the second opening 223 such that an undercut is formed. Besides, the width a1 at the bottom of the first opening 221 is also larger than the width a2 at the top of the first opening 221 such that another undercut is formed. The bottom of the second opening 223 faces the first passivation layer 203. The material of the second passivation layer 207 preferably includes photosensitive polyimide for enabling the second passivation layer 207 to absorb the stress.

Next, as shown in FIG. 2C to FIG. 2F, an UBM layer 211 is deposited on the second passivation layer 207 and the pads 205. As shown in FIG. 2D, a first photo-resist layer is formed on the UBM layer 211. Then, a portion of the UBM layer 211 is etched and the first photo-resist layer (not shown in the diagram) is removed. Then a second photo-resist layer 231 is formed and patterned such that the second photo-resist layer 231 has a number of photo-resist layer openings 240 positioned above the first openings 221. After the photo-resist layer openings 240 are formed, a conductive material 244 is filled inside the first openings 221 by printing for instance. The material of the conductive materials 244 includes tin-lead alloy. Then, the conductive material 244 is reflown and the second photo-resist layer 231 is removed to form a number of spherical bumps 213, and the base 201 is divided to form a number of chip structures 220.

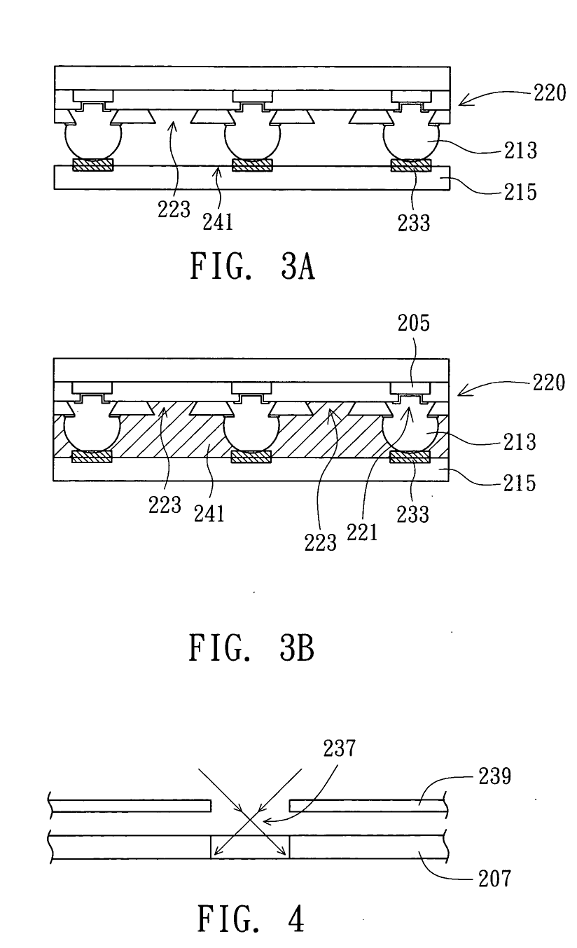

Referring to FIGS. 3A and 3B, a flowchart of forming a flip chip package is shown. As shown in FIG. 3A, after the chip structure 220 is formed, the chip structure 220 is flipped and bonded to the substrate 215. A number of connecting points 233 are disposed on the lateral side of the substrate 215 correspond to the bumps 213. The connecting points 233 are electrically connected to the bumps 213. Lastly, as shown in FIG. 3B, an under-fill 241 is filled between the chip structure 220 and the substrate 215 such that the flip chip package 200 is formed. The under-fill 241 of the flip chip package 200 flows to the second openings 223. With the trapezoid feature that the width b1 at the bottom of the second opening 223 is larger than the width b2 at the top of the second opening 223, the chip structure 220 and the substrate 215 are firmly fastened, and the chip structure 220 and the substrate 215 are more bonded.

The bonding between the bump 213 and the pad 205 is also further enhanced by the trapezoid first openings 221. Consequently, the anti-stress capability of the overall flip chip package 200 is enhanced.

Both the first openings 221 and the second openings 223 in FIG. 2B are trapezoids. That is, the width at the bottom is larger than the width at the top. The trapezoid openings are achieved either by adjusting the focal distance of exposure apparatus or by applying over development.

Referring to FIG. 4, the formation of an undercut on a second passivation layer is shown. During the formation of each first opening 221 and each second opening 223, by adjusting the exposure apparatus, the light passes through a mask 239 to be projected onto the second passivation layer 207 during exposure, and the focus of the light 237 is positioned above the second passivation layer 207 to form an acute angle with the bottom of the second passivation layer 207. After a portion of the second passivation layer 207 is removed by developing, the luminance intensity at the bottom of the second passivation layer 207 enables each first opening 221 and each second opening 223 to become a trapezoid whose bottom is larger than the top. In addition, since the light is projected above the second passivation layer 207, the area atop the second passivation layer 207 receives more energy of the light than the area underneath the second passivation layer 207. Consequently, the molecular structure at the top of the second passivation layer 207 is different from the molecular structure at the bottom of the second passivation layer 207. Furthermore, by extending the exposure time (over development), an undercut is achieved by enabling the area removed at the bottom of the second passivation layer 207 to be larger than the area removed at the top of the second passivation layer 207.

According to the flip chip package disclosed in the above embodiment of the invention, the width of the first opening at the bottom is larger than the width of the first opening at the top so that the second passivation layer retains and prevents the bump from separating the pad, while the undercut formed in the second opening enhances the retaining strength between the under-fill and the chip structure, such that the bonding between the chip structure and the substrate is enhanced. With the above structure, the anti-stress capability of the overall flip chip package is enhanced and the product reliability is improved.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A flip chip package, comprising:
a chip structure, comprising:
a base;
a plurality of pads formed on the base;
a first passivation layer formed on the base and exposes the pads; and
a second passivation layer formed on the first passivation layer, wherein the second passivation layer has a plurality of first openings and at least a second opening, the first openings are positioned on the pads, the second opening is positioned on the area other than the pads, and the width at the bottom of the second opening is larger than the width at the top of the second opening, and the bottom of the second opening faces the first passivation layer;
a plurality of bumps formed on the pad; and
a substrate having a plurality of connecting points corresponding to the bumps, wherein the connecting points are electrically connected to the bumps respectively.

2. The flip chip package according to claim 1, further comprising an under-fill filled between the substrate and the chip structure and inside the second opening.

3. The flip chip package according to claim 1, wherein the width at the bottom of the first openings is larger than the width at the top of the first openings, and the bottom of the first openings faces the first passivation layer.

4. The flip chip package according to claim 1, wherein the chip structure further comprises an under bump metallurgy (UBM) layer formed between the bump and the pad.

5. The flip chip package according to claim 1, wherein the cross-section of the first openings and the second opening is a trapezoid.

6. The flip chip package according to claim 1, wherein the material of the second passivation layer includes polyimide.

7. A method of forming a flip chip package, the method comprising:
providing a base;
forming a first passivation layer and a plurality of pads on the base, wherein the pads are exposed in the first passivation layer;
forming a second passivation layer on the first passivation layer and further forming a plurality of first openings and at least a second opening by exposure and development, the width at the bottom of the second opening is larger than the width at the top of the second opening, the bottom of the second opening faces the first passivation layer;
forming a plurality of bumps inside the first openings;
dividing the base to form a plurality of chip structures;
providing a substrate,
filing and bonding one of the chip structures on the substrate; and
filling an under-fill between the chip structure and the substrate.

8. The method according to claim 7, wherein following the step of forming the first openings, the method further comprises:
depositing an UBM layer on the second passivation layer and the pads; and
forming a first photo-resist layer on the UBM layer.

9. The method according to claim 8, wherein following the step of forming the first photo-resist layer, the method further comprises
etching a portion of the UBM layer and removing the first photo-resist layer;
forming a second photo-resist layer;
patterning the second photo-resist layer such that the second photo-resist layer has a plurality of photo-resist layer openings, wherein the photo-resist layer openings are positioned above the first openings;
filling a conductive material inside the first openings; and
reflowing the conductive material and removing the second photo-resist layer to form the bumps.

10. The method according to claim 9, wherein in the step of filling the conductive material inside the first openings, the conductive material is filled inside the first openings by printing.

11. The method according to claim 7, wherein the step of forming the second passivation layer further comprises:
coating the second passivation layer on the first passivation layer, wherein the material of the second passivation layer includes photosensitive polyimide;
applying exposure to the second passivation layer by a mask; and
applying over development to the second passivation layer to form the first openings and the second opening.

12. The method according to claim 11, wherein the step of applying exposure to the second passivation layer further comprises:
adjusting the focal distance of an exposure apparatus such that the focus of the light during exposure is positioned above the second passivation layer to form an acute angle.

13. The method according to claim 11, wherein the step of developing the second passivation layer further comprises:
controlling the duration of developing the second passivation layer such that the area etched by the developing solution at the bottom of the second passivation layer is larger than the area etched by the developing solution at the top of the second passivation layer.

14. The method according to claim 13, wherein the step of forming the second passivation layer comprises:
coating the second passivation layer on the first passivation layer, wherein the material of the second passivation layer includes photosensitive polyimide;
applying exposure to the second passivation layer by a mask, wherein the focus of the light during exposure is positioned above the second passivation layer; and
applying development to the second passivation layer to form the first openings and at least a second opening.
